(19) United States
(12) Patent Application Publication
(10) Pub. No.: US 2010/0244635 A1
(43) Pub. Date: Sep. 30, 2010

(54) PIEZOELECTRIC ELEMENT AND METHOD OF MANUFACTURING THE SAME

(75) Inventors: Shigeyoshi UMEMIYA, Kawasaki (JP); Tsuyoshi AOKI, Kawasaki (JP)

Correspondence Address: KNOBBE MARTENS OLSON & BEAR LLP, 2040 MAIN STREET, FOURTEENTH FLOOR, IRVINE, CA, 92614, US

(73) Assignee: Toshiba Storage Device Corporation, Tokyo (JP)

(21) Appl. No.: 12/748,362

(22) Filed: Mar. 26, 2010

(30) Foreign Application Priority Data
Mar. 27, 2009 (JP) 2009-078925

(51) Int. Cl. H01L 41/047; H04R 17/00

(52) U.S. Cl. 310/365; 29/25.35

(57) ABSTRACT

According to one embodiment, a piezoelectric element is provided by forming a first electrode film on a major surface of a substrate, forming a modified film by modifying at least a portion of the major surface of the substrate by heating the substrate in an ambient containing oxygen, and forming a piezoelectric film by depositing a piezoelectric material on the first electrode film, forming a second electrode film on the piezoelectric film, adhering a support on the second electrode film, and peeling off a multilayered structure including at least the first electrode film, the piezoelectric film, the second electrode film, and the support from the substrate.

### CROSS-REFERENCE TO RELATED APPLICATIONS

This application is based upon and claims the benefit of priority from Japanese Patent Application No. 2009-078925, filed Mar. 27, 2009, the entire contents of which are incorporated herein by reference.

### BACKGROUND

1. Field

One embodiment of the present invention relates to a piezoelectric element suitable for, e.g., a sensor that outputs a voltage corresponding to a deformation amount and an actuator driven by the application of a voltage, and a method of manufacturing the piezoelectric element.

2. Description of the Related Art

As disclosed in, e.g., Jpn. Pat. Appln. KOKAI Publication Nos. 2003-168270 and 2008-196926, piezoelectric elements are recently beginning to be widely used as, e.g., an acceleration sensor, pressure sensor, and actuator of electronic devices such as a magnetic disk device. This piezoelectric element generally has a structure in which a piezoelectric film is sandwiched between electrode films. A voltage is generated between the electrode films when stress acts in a direction to expand, contract, or bend the piezoelectric film. Also, when a voltage is applied between the electrode films sandwiching the piezoelectric film, the piezoelectric film expands or contracts in directions parallel and perpendicular to the film surface.

Accordingly, a sensor for sensing the pressure or acceleration can be formed by mounting the piezoelectric element on a support that deforms owing to the pressure or acceleration. The piezoelectric element can also be used as an actuator or the like when attached to, e.g., a cantilever.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view showing the structure of a head gimbal assembly;

FIGS. 2A, 2B, 2C, and 2D are first sectional views showing, in the order of steps, a method of manufacturing piezoelectric elements to be used in a head gimbal assembly according to the first embodiment;

FIGS. 3A, 3B, and 3C are second sectional views showing, in the order of steps, the method of manufacturing the piezoelectric elements to be used in the head gimbal assembly according to the first embodiment;

FIGS. 4A and 4B are third sectional views showing, in the order of steps, the method of manufacturing the piezoelectric elements to be used in the head gimbal assembly according to the first embodiment;

FIG. 5 is a plan view showing a structure in which the piezoelectric elements are mounted on the surface of a flexure;

FIG. 6 is a plan view showing a structure in which the flexure shown in FIG. 5 is attached to a load beam; and

FIG. 7 is a graph showing the measurement results of the adhesion strength of the interface between a substrate and modified layer as a function of the thickness of a piezoelectric film.

### DETAILED DESCRIPTION

Various embodiments according to the invention will be described hereinafter with reference to the accompanying drawings. In general, according to one embodiment of the invention, a method of manufacturing a piezoelectric element is provided which includes

forming a first electrode film on a major surface of a substrate,

forming a modified film by modifying at least a portion of the major surface of the substrate by heating the substrate in an ambient containing oxygen, and forming a piezoelectric film by depositing a piezoelectric material on the first electrode film,

forming a second electrode film on the piezoelectric film,

adhering a support on the second electrode film, and

peeling off a multilayered structure including at least the first electrode film, the piezoelectric film, the second electrode film, and the support from the substrate.

A piezoelectric element according to another aspect of the present invention is a piezoelectric element formed by using an example of the piezoelectric element manufacturing method described above, and includes

a support,

a second electrode film adhered on a surface of the support,

a piezoelectric film formed on the second electrode film,

a first electrode film formed on the piezoelectric film, and

a modified layer formed on the first electrode film by a reaction of AlTiC with oxygen.

A method of manufacturing a head gimbal assembly according to still another aspect of the present invention is a method of manufacturing, by applying the above-mentioned piezoelectric element manufacturing method, a head gimbal assembly including a plate-like load beam having elasticity, a plate-like flexure which is connected to a distal end portion of the load beam and supports a slider, and a piezoelectric element mounted on the flexure, and includes

forming a first electrode film on a major surface of a substrate,

forming a modified layer by modifying at least a portion of the major surface of the substrate by heating the substrate in an ambient containing oxygen, and forming a piezoelectric film by depositing a piezoelectric material on the first electrode film,

forming a second electrode film on the piezoelectric film,

adhering the flexure on the second electrode film,

peeling off a multilayered structure including the first electrode film, the piezoelectric film, the second electrode film, and the flexure from the substrate,

attaching the slider to the flexure, and

connecting the flexure to the load beam.

In the present invention, the piezoelectric film is formed by depositing the piezoelectric material in an oxygen-containing ambient while heating the substrate. In the formation of this piezoelectric film, oxygen in the ambient diffuses in the substrate surface and reacts with the portion near the surface of the substrate, thereby forming the modified layer that readily peels off from the substrate. After that, the second electrode film is formed on the piezoelectric film, and the support is adhered on the second electrode film by an adhesive and peeled off from the substrate. Since the adhesion strength between the substrate and modified layer is lower than that between the second electrode film and support, the interface portion between the substrate and modified layer peels off, and the piezoelectric element (the multilayered structure including the first electrode film, piezoelectric film, and second electrode film) formed above the modified layer is transferred onto the support.

The piezoelectric element is thus separated from the substrate, and hence can be made thinner than the conventional piezoelectric element. Also, as the substrate does not interfere with the deformation of the piezoelectric element and support, the sensitivity can further be increased when the piezoelectric element is used as a sensor.

Embodiments will be explained below with reference to the accompanying drawing.

### First Embodiment

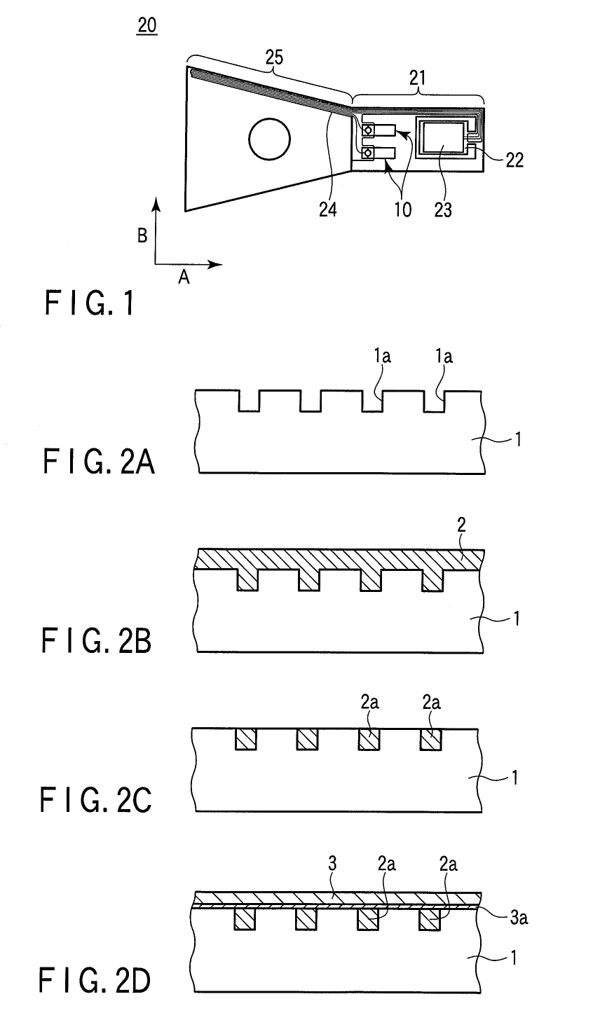

In the first embodiment, a piezoelectric element is used as an acceleration sensor for sensing the change in floating amount of a magnetic head of a magnetic disk device, and the piezoelectric element is incorporated into a head gimbal assembly. FIG. 1 is a plan view showing the structure of the head gimbal assembly.

As shown in FIG. 1, a head gimbal assembly 20 includes a flexure 21 including a slider 23 and a pair of piezoelectric elements 10, and a load beam 25 for supporting the flexure 21. The load beam 25 and flexure 21 are made of, e.g., a stainless steel plate about 20 μm thick. The slider 23 is placed in a gimbal portion 22 formed in the flexure 21, i.e., in a portion surrounded by a “C”-shaped notch shown in FIG. 1. The slider 23 has a magnetic head (not shown) for recording data on or reproducing data from a magnetic disk.

The pair of piezoelectric elements 10 are arranged on the flexure 21 at a predetermined interval in a track width direction, i.e., a direction indicated by an arrow B. The number of piezoelectric elements 10 formed on the flexure 21 is not limited to two, and it is also possible to arrange one piezoelectric element or three or more piezoelectric elements. The structure of the piezoelectric element 10 will be described in detail later together with the manufacturing steps.

A flexible circuit board 24 having a plurality of lines for electrically connecting the piezoelectric elements 10 and the magnetic head (not shown) formed on the slider 23 to external circuits is placed on the load beam 25 and flexure 21. Some lines of the flexible circuit board 24 are connected to plug electrodes projecting from the upper portions of the piezoelectric elements 10. Some other lines of the flexible circuit board 24 extend to the vicinity of the gimbal portion 22, and are electrically connected to the magnetic head via, e.g., bonding wires. The plug electrodes will be described later.

A method of manufacturing the head gimbal assembly 20 and a method of manufacturing the piezoelectric elements 10 will be explained below with reference to FIGS. 2A, 2B, 2C, 2D, 3A, 3B, 3C, 4A, 4B, 5, and 6.

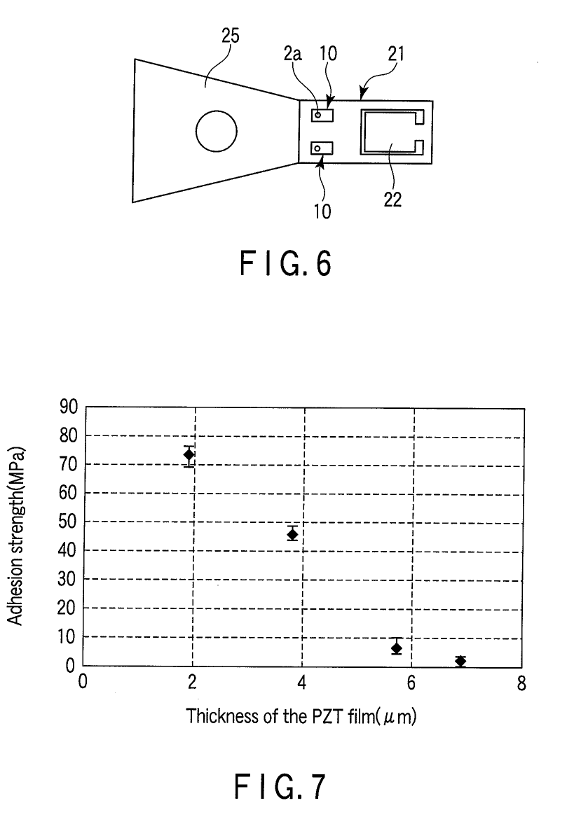

FIGS. 2A, 2B, 2C, 2D, 3A, 3B, 3C, 4A, and 4B are sectional views showing, in the order of steps, the method of manufacturing the piezoelectric elements to be used in the head gimbal assembly according to the first embodiment. FIG. 5 is a plan view showing a structure in which the piezoelectric elements are mounted on the surface of the flexure. FIG. 6 is a plan view showing a structure in which the flexure shown in FIG. 5 is attached to the load beam. Note that FIGS. 2A, 2B, 2C, 2D, 3A, 3B, 3C, 4A, and 4B illustrate an example in which four piezoelectric elements are simultaneously formed on a substrate. However, this embodiment is not limited to this example, and it is also possible to simultaneously form a larger number of piezoelectric elements.

First, as shown in FIG. 2A, a substrate (to be referred to as an AlTiC substrate hereinafter) 1 having a thickness of about 2 mm and made of a sintered material containing alumina (Al₂O₃) and titanium nitride (TiC) is prepared. Recesses 1a having a diameter of 100 μm and a depth of 500 nm are formed in the surface of the AlTiC substrate 1 by photolithography and dry etching. Note that the recesses 1a may also be formed by sandblasting using a metal mask because the diameter of the recesses 1a is as large as about 100 μm.

Then, as shown in FIG. 2B, platinum (Pt) is deposited by sputtering or the like on the surface of the AlTiC substrate 1 so as to fill the recesses 1a, thereby forming a conductor film 2.

As shown in FIG. 2C, the conductor film 2 is polished until the upper surface of the AlTiC substrate 1 is exposed, so it is left behind in only the recesses 1a. The conductor film 2 remaining in each recess 1a functions as a plug electrode 2a.

As shown in FIG. 2D, titanium (Ti) is deposited by a thickness of about 10 nm by sputtering or the like on the entire upper surface of the plug electrodes 2a and AlTiC substrate 1, thereby forming an adhesion film 3a. Subsequently, a first electrode film 3 is formed by depositing platinum (Pt) by a thickness of about 150 nm on the adhesion film 3a by sputtering or the like. The adhesion film 3a has the effects of increasing the adhesion between the first electrode film 3 and the surface of the AlTiC substrate 1, and increasing the crystallinity of a piezoelectric film 4 (e.g., a PZT film) to be formed next.

The first electrode film 3 may also be formed by using, instead of platinum, a noble metal such as iridium (Ir) or ruthenium (Ru), a noble metal oxide such as iridium oxide (IrO) or ruthenium oxide (RuO), or a conductive oxide such as SRO (SrRuO). This similarly applies to the material of the plug electrodes 2a described above, and the material of a second electrode film 6 to be described later. The above-mentioned adhesion film 3a and first electrode film 3 are deposited by sputtering by supplying argon gas or the like at a substrate temperature of, e.g., about 540° C.

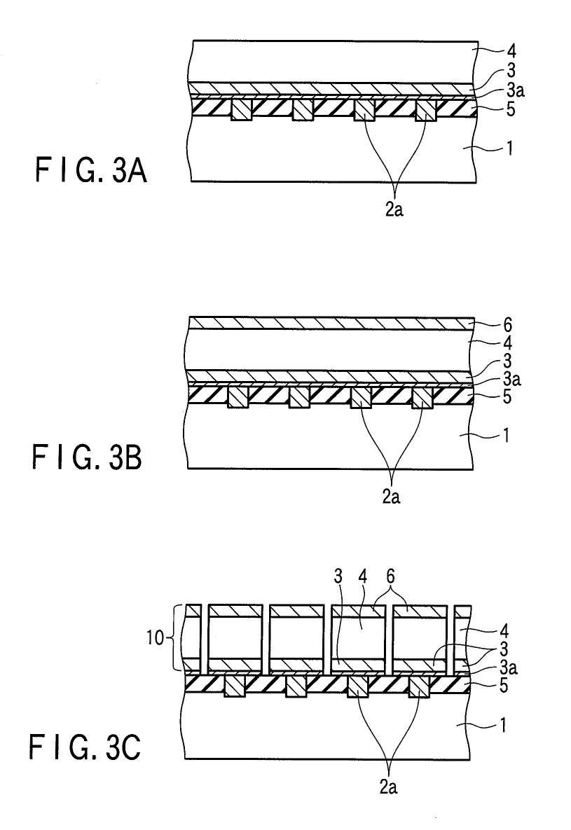

Then, as shown in FIG. 3A, PZT (lead zirconate titanate) is deposited by a thickness of, e.g., 5 μm on the first electrode film 3 by sputtering, thereby forming a piezoelectric film 4. In this step, the substrate temperature is set at 540° C., and a gas mixture containing argon gas and oxygen gas at a ratio of 9:1 is supplied into a chamber. The substrate temperature can be about 500° C. to 600° C., and the ratio of argon gas to oxygen gas can be about 9.5:0.5 to 8:2. Also, the thickness of the piezoelectric film 4 is favorably 5 μm or more because this facilitates peeling off piezoelectric elements 10 from the substrate 1 as will be described later.

In this step of forming the piezoelectric film 4, the substrate temperature is high, and oxygen is contained in the ambient and in a piezoelectric target. Therefore, oxygen diffuses in the first electrode film 3, reaches the surface of the AlTiC substrate 1, and reacts with AlTiC to form a modified layer 5. The modified layer 5 is presumably formed by the reaction of titanium carbide (TiC) contained in the AlTiC substrate 1 with oxygen. When stress is applied, the modified layer 5 readily peels off from the AlTiC substrate 1.

As shown in FIG. 3B, a second electrode film 6 is formed by depositing, e.g., platinum (Pt) by a thickness of about 150 nm on the piezoelectric film 4.

As shown in FIG. 3C, rectangular masks (not shown) having dimensions of, e.g., about 0.5 mm×1.0 mm are formed on predetermined regions of the second electrode film 6 by photolithography. Subsequently, the second electrode film 6, piezoelectric film 4, first electrode film 3, and adhesion film 3a are removed from unmasked portions by dry etching. Multilayered structures separated from each other in this etching step and including the adhesion film 3a, first electrode film 3, piezoelectric film 4, and second electrode film 6 are the piezoelectric elements 10. Note that the dry etching of the second electrode film 6, first electrode film 3, and adhesion film 3a is performed using, e.g., a chlorine-containing etching gas, and the dry etching of the piezoelectric film 4 is performed using, e.g., a fluorine-containing etching gas.

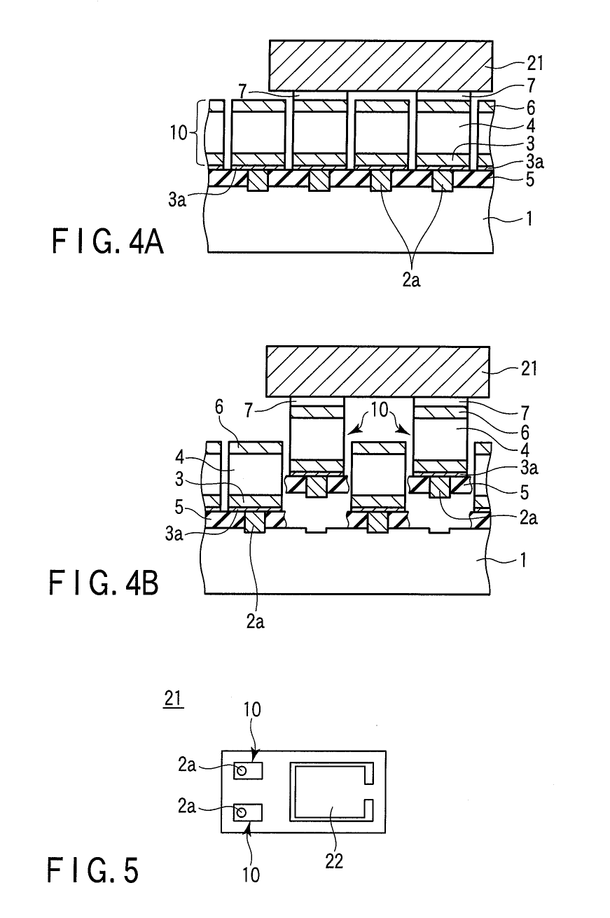

As shown in FIG. 4A, conductive adhesive layers 7 made of, e.g., an uncured epoxy resin containing silver powder are formed on the second electrode films 6. FIG. 4A shows an example in which the adhesive layers 7 are formed on only two piezoelectric elements 10 each including the adhesion film 3a, first electrode film 3, piezoelectric film 4, and second electrode film 6. After that, the flexure 21 (support) made of a stainless steel plate having a thickness of, e.g., about 20 μm is adhered on the adhesive layers 7. The AlTiC substrate 1 and flexure 21 are annealed at a temperature of, e.g., 150° C. for about one hour, thereby curing the adhesive layers 7.

As shown in FIG. 4B, the flexure 21 is peeled off from the AlTiC substrate 1. Since the adhesion strength of the interface between the modified layer 5 and AlTiC substrate 1 is lower than that between the adhesive layer 7 and second electrode film 6 and that between the adhesive layer 7 and flexure 21, the modified layer 5 peels off from the substrate 1, and the piezoelectric elements 10 are transferred onto the flexure 21. In this step, the two piezoelectric elements 10 are transferred onto the flexure 21 because the adhesive layers 7 are formed on the two piezoelectric elements 10. In this manner, the thin piezoelectric elements 10 separated from the substrate 1 can be formed on the flexure 21. Also, the plug electrode 2a formed below the first electrode film 3 projects from the modified layer 5 and is exposed. Therefore, the plug electrode 2a can be used as a terminal when connecting a wiring material. The flexure 21 shown in FIG. 5 is completed by the above-mentioned steps.

Then, as shown in FIG. 6, the flexure 21 is connected to the load beam 25 by, e.g., spot welding. After that, the slider 23 is attached to the gimbal portion 22 by an adhesive. In addition, the flexible circuit board 24 is mounted on the surfaces of the flexure 21 and load beam 25, and the plug electrodes 2a of the piezoelectric elements 10 are electrically connected to some lines (not shown) of the flexible circuit board 24 by, e.g., a conductive adhesive. Also, other lines of the flexible circuit board 24 are electrically connected to a magnetic head by wire bonding or the like. The head gimbal assembly 20 shown in FIG. 1 is completed by the steps described above.

In a magnetic disk device (not shown), the head gimbal assembly 20 is installed such that the surface shown in FIG. 1 faces a magnetic disk (not shown). The proximal end (the left end shown in FIG. 1) of the head gimbal assembly 20 is connected to a voice coil motor (not shown) of the magnetic disk device, and the head gimbal assembly 20 is driven by this voice coil motor. The magnetic disk relatively moves in a direction indicated by an arrow A shown in FIG. 1 with respect to the slider 23.

The piezoelectric elements 10 deform together with the flexure 21, and output a voltage corresponding to the deformation amount of the flexure 21. Based on the outputs from the pair of piezoelectric elements 10, it is possible to detect the deformation in the roll direction (the axial direction parallel to the arrow A) and the deformation in the floating height direction (the direction perpendicular to the drawing surface of FIG. 1) of the flexure 21. The piezoelectric element 10 of this embodiment is formed thin (e.g., about a few μm) as it is separated from the substrate 1, and hence has little effect on the flexural rigidity of the flexure 21. Accordingly, the piezoelectric element 10 does not interfere with the deformation of the flexure 21. This makes it possible to more accurately detect the floating amount of the slider 23.

Furthermore, the piezoelectric element 10 of this embodiment has a small thickness and can be mounted on the flexure 21 having a small packaging space in the direction of thickness.

The results of measurements performed on the adhesion strength between the AlTiC substrate and modified layer by changing the thickness of the piezoelectric film will be explained below.

First, the piezoelectric elements 10 were formed on the AlTiC substrate 1 by the method shown in FIGS. 2A, 2B, 2C, 2D, 3A, 3B, 3C, 4A, and 4B.

When forming the piezoelectric film (PZT film) 4, the substrate temperature was set at about 540° C., and the ratio of argon gas to oxygen gas to be supplied into a chamber was set at 9:1.

Then, the section of the piezoelectric element 10 formed under the above conditions was observed with a TEM (Transmission Electron Microscope). Consequently, the modified layer 5 about 100 to 200 nm thick was formed below the adhesion film 3a. The modified layer 5 was presumably formed because titanium carbide (TiC) contained in the AlTiC substrate 1 reacted with oxygen contained in the ambient.

Subsequently, samples were formed by changing the thickness of the PZT film (piezoelectric film 4) from about 2 μm to about 7 μm under the above-mentioned deposition conditions, and the adhesion strength of the interface between the modified layer 5 and AlTiC substrate 1 was checked for each sample. FIG. 7 shows the results. FIG. 7 reveals that as the thickness of the PZT film increases, the adhesion strength of the interface between the modified layer 5 and AlTiC substrate 1 decreases.

Also, when the thickness of the PZT film was 2 μm, it was difficult to peel off the piezoelectric element 10 from the AlTiC substrate 1, and the adhesive layer 7 peeled off when the peel force was strong. On the other hand, when the thickness of the PZT film was 5 μm, it was possible to reliably peel off the modified layer 5 from the AlTiC substrate 1. This demonstrates that the thickness of the PZT film may be 5 μm or more.

### Other Embodiments

In the first embodiment, the example in which the piezoelectric element 10 is mounted on the head gimbal assembly 20 is explained. However, a member on which the piezoelectric element 10 is mounted is not limited to the head gimbal assembly. For example, a thin piezoelectric sensor can be obtained by transferring the piezoelectric element 10 onto a support such as a metal foil or resin film, instead of the flexure 21. As an example, the piezoelectric element 10 can be used as an acceleration sensor by processing a support into the form of a leaf spring so that the support deforms in accordance with the acceleration.

Furthermore, the piezoelectric element 10 can also be used as an actuator instead of a sensor.

For example, the piezoelectric element 10 as shown in FIG. 1 can also be used as an actuator for controlling the floating amount of a magnetic head attached to the head gimbal assembly 20.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing a piezoelectric element, comprising:
forming a first electrode film on a surface of a substrate;
forming a modified film by modifying at least a portion of the surface of the substrate by heating the substrate in an ambient containing oxygen, and forming a piezoelectric film by depositing a piezoelectric material on the first electrode film;
forming a second electrode film on the piezoelectric film;
attaching a support to the second electrode film; and
removing a multilayered structure from the substrate, the multilayered structure comprising the first electrode film, the piezoelectric film, the second electrode film, and the support.

2. The method of claim 1, wherein at least a portion of the surface of the substrate comprises AlTiC.

3. The method of claim 1, further comprising forming an adhesion film comprising titanium on the surface of the substrate before forming the first electrode film.

4. The method of claim 3, further comprising forming a plug electrode before forming the adhesion film, wherein forming the plug electrode comprises:
forming a recess in the surface of the substrate;
depositing a conductor film on the surface of the substrate including the recess; and
removing at least a portion of the conductor film by polishing such that at least a portion of the conductor film remains in the recess, thereby forming a plug electrode;
wherein the surface of the substrate comprises a surface of the plug electrode.

5. The method of claim 1, wherein forming the piezoelectric film comprises heating the substrate to a temperature between about 500° C. and about 600° C.

6. A piezoelectric element comprising:
a support;
a first electrode film on a surface of the support;
a piezoelectric film on the first electrode film;
a second electrode film on the piezoelectric film; and
a modified layer on the second electrode film, the modified layer comprising a reaction product of AlTiC and oxygen.

7. A method of manufacturing a head gimbal assembly comprising a load beam, a flexure which is connected to a distal portion of the load beam and supports a slider, and a piezoelectric element mounted on the flexure, comprising:
forming a first electrode film on a surface of a substrate;
forming a modified layer by modifying at least a portion of the surface of the substrate by heating the substrate in an ambient containing oxygen, and forming a piezoelectric film by depositing a piezoelectric material on the first electrode film;
forming a second electrode film on the piezoelectric film;
attaching the flexure to the second electrode film;
removing a multilayered structure from the substrate, the multilayered structure comprising the first electrode film, the piezoelectric film, the second electrode film, and the flexure;
attaching the slider to the flexure; and
connecting the flexure to the load beam.

8. The method of claim 7, wherein at least a portion of the surface of the substrate comprises AlTiC.

9. The method of claim 7, further comprising forming an adhesion film comprising titanium on the surface of the substrate before the first electrode film is formed.

10. The method of claim 9, further comprising forming a plug electrode before forming the adhesion film, wherein forming the plug electrode comprises:
forming a recess in the surface of the substrate,
depositing a conductor film on the surface of the substrate including the recess,
removing at least a portion of the conductor film by polishing such that at least a portion of the conductor film remains in the recess, thereby forming a plug electrode;
wherein the surface of the substrate comprises a surface of the plug electrode.

11. The method of claim 7, wherein forming the piezoelectric film comprises heating the substrate to a temperature between about 500° C. and about 600° C.
